(19) United States
(12) Patent Application Publication
(10) Pub. No.: US 2024/0188255 A1
(43) Pub. Date: Jun. 6, 2024

(54) HEAT EXCHANGE ENHANCED MODULE SHELL

(71) Applicant: Molex, LLC, Lisle, IL (US)

(72) Inventors: Taolue Zhang, Naperville, IL (US); Nabhanshul Satra, Naperville, IL (US); Saiyed Muhammad Hasan Ali, Conway, AR (US); Peerouz Amleshi, Lisle, IL (US)

(21) Appl. No.: 18/388,539

(22) Filed: Nov. 10, 2023

Related U.S. Application Data
(60) Provisional application No. 63/430,352, filed on Dec. 6, 2022.

(51) Int. Cl. H05K 7/20

(52) U.S. Cl. CPC H05K 7/20409; H05K 7/20445; H05K 7/20509

(57) ABSTRACT

Aspects of heat exchange enhanced module shells for pluggable transceiver modules are described. In one example, a pluggable transceiver module includes a module shell. The module shell includes an upper shell and a lower shell. The upper shell includes a planar inner surface and a recessed area formed into the planar inner surface. The module also includes a printed circuit board, a chip mounted on the printed circuit board, and a heat spreader secured within the recessed area, between the upper shell and the chip. The heat spreader can be a heat pipe, a vapor chamber, or a related heat spreading structure. The heat spreader helps to transfer the heat from the chip across a larger area of the upper shell of the module. The heat can be more effectively transferred to a heat sink of a mating connector or cage for the pluggable transceiver module.

### RELATED APPLICATION

This application claims priority to U.S. Provisional Application No. 63/430,352 filed Dec. 6, 2022, which is incorporated herein by reference in its entirety.

### BACKGROUND ART

The amount of data processed by computers, computing systems, and computing environments continues to increase. For example, data centers can include hundreds of computing and networking systems interconnected using optical cables, copper cables, and various connectors, cable assemblies, and terminations between them. The data throughput of these interconnects is high and increasing. As examples, many data centers incorporate a combination of 10 Gigabit Ethernet (10 GbE), 25 GbE, 50 GbE, and 100 GbE network interfaces and interconnects. 200 GbE, 400 GbE, and 800 GbE interconnection technology is also being developed and deployed. Other interconnection solutions rely upon 56 Gigabit per second (Gb/s) and 112 Gb/s network interfaces and interconnects, and 224 Gb/s interconnection technology is being developed. A range of cable assemblies are available for the data interconnects. A variety of designs exist for each cable assembly, depending on the requirements of the data communications environment in which the connectors are used.

The small form-factor pluggable (SFP) module format is a compact, hot-pluggable network interface module format used for data interconnects. An SFP interface on a computing or networking system is a modular slot for a media-specific transceiver, such as a fiber-optic or a copper cable. Cable assemblies can include SFP pluggable transceiver modules at one or both ends of a copper, fiber-optic, or other type of interconnecting cable. SFP pluggable transceiver modules can be inserted into SFP interfaces for data interconnections. The quad small form-factor pluggable (QSFP) module format is one example of a high density SFP cabling interconnect system. QSFP cable assemblies are designed to meet high performance data center interconnect applications.

### SUMMARY

Aspects of heat exchange enhanced module shells for pluggable transceiver modules are described. In one example, a pluggable transceiver module includes a module shell. The module shell includes an upper shell and a lower shell. The upper shell includes a planar inner surface and a recessed area formed into the planar inner surface. The module also includes a printed circuit board, a semiconductor chip mounted on the printed circuit board, and a heat spreader secured within the recessed area, between the upper shell and the semiconductor chip. In some cases, a thermal pad is positioned between the semiconductor chip and the heat spreader. The heat spreader can be embodied as a heat pipe or a vapor chamber, among related types of heat spreaders.

In one example, the heat spreader is welded to the upper shell. In another example, heat spreader is sintered to the upper shell with silver sinter die attach. In another case, the module shell includes a die cast module shell, and the heat spreader is a die cast insert in the die cast module shell. In still another example, the heat spreader includes an interlocking ledge, and the upper shell secures the heat spreader within the recessed area by mechanical interference with the interlocking ledge. The heat spreader can be secured within the recessed area with a surface of the heat spreader being substantially coplanar with the planar inner surface of the upper shell.

In other aspects, the heat spreader includes a positioning detent, the upper shell comprises a recess notch, and the heat spreader is secured within the recessed area with the positioning detent extending into the recess notch. The module can also include an insulating sheet extending over at least a portion of the heat spreader in some cases. In other aspects, the heat spreader extends in length over at least half of a length of the upper shell, along a longitudinal axis of the upper shell.

In another embodiment, a transceiver module includes a module shell comprising a planar inner surface and a recessed area formed into the planar inner surface, a semiconductor chip mounted on a printed circuit board, and a heat spreader secured within the recessed area, between the module shell and the semiconductor chip. The heat spreader can be secured within the recessed area with a surface of the heat spreader being substantially coplanar with the planar inner surface of the module shell.

In one aspect, the heat spreader is welded within the recessed area of the module shell. In other case, the heat spreader is sintered within the recessed area of the module shell with silver sinter die attach. In another case, the module shell includes a die cast module shell, and the heat spreader is a die cast insert in the die cast module shell. In still another example, the heat spreader includes an interlocking ledge, and the upper shell secures the heat spreader within the recessed area by mechanical interference with the interlocking ledge. The heat spreader can be secured within the recessed area with a surface of the heat spreader being substantially coplanar with the planar inner surface of the upper shell.

In other aspects, the heat spreader includes a positioning detent, the module shell comprises a recess notch, and the heat spreader is secured within the recessed area with the positioning detent extending into the recess notch. The module can also include an insulating sheet extending over at least a portion of the heat spreader in some cases. In other aspects, the heat spreader extends in length over at least half of a length of the module shell, along a longitudinal axis of the module shell.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIG. 1 illustrates a perspective view of an interconnect assembly according to various embodiments of the present disclosure.

FIG. 2 illustrates a perspective view of the interconnect assembly shown in FIG. 1, with heat sink omitted, according to various embodiments of the present disclosure.

FIG. 3 illustrates a perspective view of the cable assembly shown in FIG. 1 according to aspects of the present disclosure.

FIG. 4 illustrates the cross-sectional view of the cable assembly designated I-I in FIG. 1 according to aspects of the present disclosure.

FIG. 5 illustrates a bottom view of an upper shell of a module shown in FIG. 3 according to aspects of the present disclosure.

FIG. 6A illustrates a bottom view of an upper shell of another cable assembly according to various embodiments of the present disclosure.

FIG. 6B illustrates the upper shell shown in FIG. 6A, with a heat pipe, according to various embodiments of the present disclosure.

FIG. 7 illustrates a heat pipe according to various embodiments of the present disclosure.

FIG. 8 illustrates a cross-sectional view of a cable assembly including the upper shell and heat pipe shown in FIG. 6B according to aspects of the present disclosure.

FIG. 9A illustrates the cross-sectional view of the upper shell and heat pipe designated II-II in FIG. 6B according to aspects of the present disclosure.

FIG. 9B illustrates a cross-sectional view of another upper shell and heat pipe according to aspects of the present disclosure.

FIG. 10A illustrates a bottom view of an upper shell of another cable assembly according to various embodiments of the present disclosure.

FIG. 10B illustrates the upper shell shown in FIG. 10A, with a vapor chamber, according to various embodiments of the present disclosure.

FIG. 11 illustrates a vapor chamber according to various embodiments of the present disclosure.

FIG. 12 illustrates a cross-sectional view of a cable assembly including the upper shell and heat pipe shown in FIG. 10B according to aspects of the present disclosure.

FIG. 13A illustrates the cross-sectional view of the upper shell and heat pipe designated III-III in FIG. 10B according to aspects of the present disclosure.

FIG. 13B illustrates a cross-sectional view of another upper shell and heat pipe according to aspects of the present disclosure.

### DETAILED DESCRIPTION

The amount of data processed by computers, computing systems, and computing environments continues to increase. For example, data centers can include hundreds of computing and networking systems interconnected using optical cables, copper cables, and various connectors, cable assemblies, and terminations between them. The small form-factor pluggable (SFP) module format is a compact, hot-pluggable network interface module format used for data interconnects. An SFP interface on a computing or networking system is a modular slot for a media-specific transceiver, such as a fiber-optic or a copper cable. Cable assemblies can include SFP pluggable transceiver modules at one or both ends of a copper, fiber-optic, or other type of interconnecting cable. SFP pluggable transceiver modules can be inserted into SFP interfaces for data interconnections.

A range of SFP pluggable transceiver modules are currently available, including small form-factor pluggable double density (SFP-DD), compact small form-factor pluggable (cSFP), SFP+, quad small form-factor pluggable (QSFP), quad small form-factor pluggable double density (QSFP-DD), and others. SFP pluggable transceiver modules often include one or more packaged semiconductor circuit devices or chips. An active electrical cable (AEC) assembly with SFP pluggable transceiver modules, for example, can include a packaged semiconductor chip for signal re-timing. AEC assembly semiconductor chips can reset loss and timing planes for data signals, remove noise, and improve signal integrity, among other functions. An active optical cable (AOC) assembly with SFP pluggable transceiver modules, for example, can include a packaged semiconductor chip for converting optical signals to electrical signals. Semiconductor chips in AOC's can include receiver optical subassemblies (ROSAs) configured to receive optical signals transmitted by transmitter optical subassemblies (TOSAs). The ROSAs are configured to convert the optical signals back to electrical signals.

The semiconductor chips in SFP pluggable transceiver modules consume power and dissipate heat. As new cable assemblies are designed to transmit data at higher rates, the semiconductor chips can consume more power, dissipate more heat, or both, and it can be important to dissipate the heat from the semiconductor chips, to protect the semiconductor chips from failure. Many connectors and cages for SFP pluggable transceiver modules include heat sinks and other means to remove and dissipate the heat from the modules. However, SFP modules are not necessarily optimized for the transfer of heat from the semiconductor chips within the modules to the heat sinks on the SFP connectors and cages.

In the context outlined above, aspects of heat exchange enhanced module shells for pluggable transceiver modules are described. In one example, a pluggable transceiver module includes a module shell. The module shell includes an upper shell and a lower shell. The upper shell includes a planar inner surface and a recessed area formed into the planar inner surface. The module also includes a printed circuit board, a semiconductor chip or device mounted on the printed circuit board, and a heat spreader secured within the recessed area, between the upper shell and the semiconductor chip. The heat spreader can be a heat pipe, a vapor chamber, or a related heat spreading structure. The heat spreader helps to transfer the heat from the semiconductor chip across a larger area of the upper shell of the module. The heat can be more effectively transferred to a heat sink of a mating connector or cage for the pluggable transceiver module.

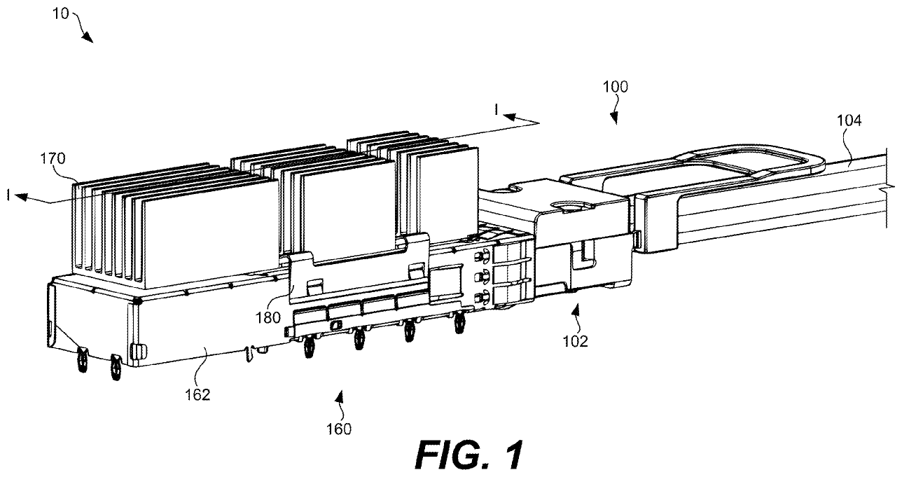

Turning to the drawings, FIG. 1 illustrates a perspective view of an example interconnect assembly 10 according to various embodiments of the present disclosure. The interconnect assembly 10 includes a cable assembly 100 and a cage 160. The cage 160 includes a metal housing 162, a heat sink 170, and a clip 180 that secures the heat sink 170 over the cage 160, among other components. The clip 180 engages with side walls of the cage 160 to secure the heat sink 170 over the cage 160. The cable assembly 100 includes a pluggable transceiver module 102 (also “module 102”) at one end of a cable 104. The metal housing 162 of the cage 160 surrounds an open space into which the module 102 can be inserted, as described in further detail below. The heat sink 170 may include vertically-oriented fins spaced apart from one another that allow for heat dissipation.

The interconnect assembly 10 is representative, not drawn to any particular scale, and is illustrated to provide context for the concepts of pluggable transceiver modules having modules shells with features for enhanced heat exchange. The cable assembly 100 is not intended to be limited to any particular type of cable or cable assembly, and the cable 104 can be embodied as a fiber optic, copper, or other type of cable. Thus, the cable assembly 100 is an example of an AEC, and AOC, or related type of cable. The module 102, which is described in further detail below, is also representative, and the concepts described herein can be applied to a range of pluggable modules, including SFP, SFP-DD, cSFP, SFP+, QSFP, QSFP-DD, and related types of pluggable modules. The cage 160 can be mounted to a printed circuit board (PCB) (not shown) of a computing, networking, or related system. The cage 160 can vary in size and style as compared to that shown, depending on the type, style, and size of the module 102. A connector within the cage 160 is designed to mate with a PCB-style tip at the end of the module 102, when the module 102 is fully inserted within the cage 160, as shown in FIG. 1.

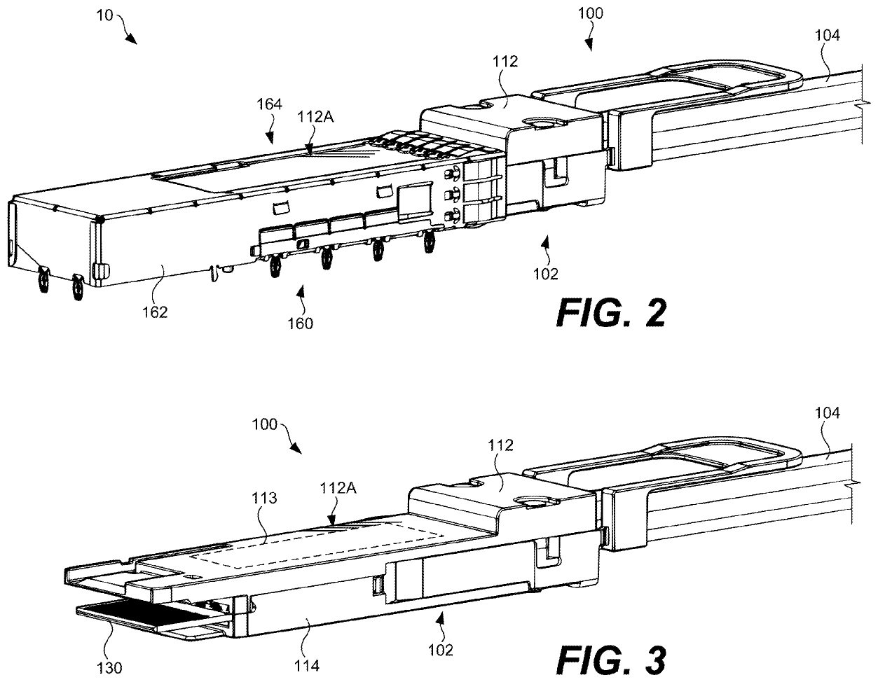

FIG. 2 illustrates a perspective view of the interconnect assembly 10 shown in FIG. 1, with the heat sink 170 omitted. FIG. 3 illustrates a perspective view of the cable assembly 100 shown in FIG. 1, separate from the cage 160. The metal housing 162 of the cage 160 includes an opening 164, as shown in FIG. 2. The module 102 includes a module shell that encloses a number of components, such as a PCB, one or more semiconductor chips mounted on the PCB, and other components. The module shell of the module 102 includes upper shell 112, a lower shell 114, and other components. A region 113 of the upper shell 112 is exposed through the opening 164 in the metal housing 162, as shown in FIGS. 2 and 3, such that a top outer surface 112A of the upper shell 112 is exposed through the opening 164. The top outer surface 112A is planar in the example shown, particularly where it is exposed through the opening 164.

The upper shell 112 and lower shell 114 of the module 102 can be embodied as or formed from a metal or metal alloy. In one example, the upper shell 112 and lower shell 114 can be embodied as a die-cast zinc, zinc alloy, or other metals or metal alloys. The upper shell 112 and lower shell 114 can be plated on exterior surfaces in some cases, such as with one or more copper, nickel, or other plating layers. The materials from which the module shell of the module 102 is formed is not limited, however, and the module shell can be formed from a range of materials and manufacturing techniques.

The one or more semiconductor chips in the module 102 consume power and dissipate heat. The heat is conducted, at least in part, through the upper shell 112 of the module 102. A bottom surface of the heat sink 170 contacts the top outer surface 112A of the upper shell 112 through the opening 164 in the top of the housing 162. The clip 180 engages with the side walls of the cage 160 to secure the heat sink 170 over the cage 160, with the bottom surface of the heat sink 170 being in planar contact with the top outer surface 112A of the upper shell 112. Thus, the heat sink 170 is positioned to draw and dissipate heat away from the upper shell 112 of the module 102.

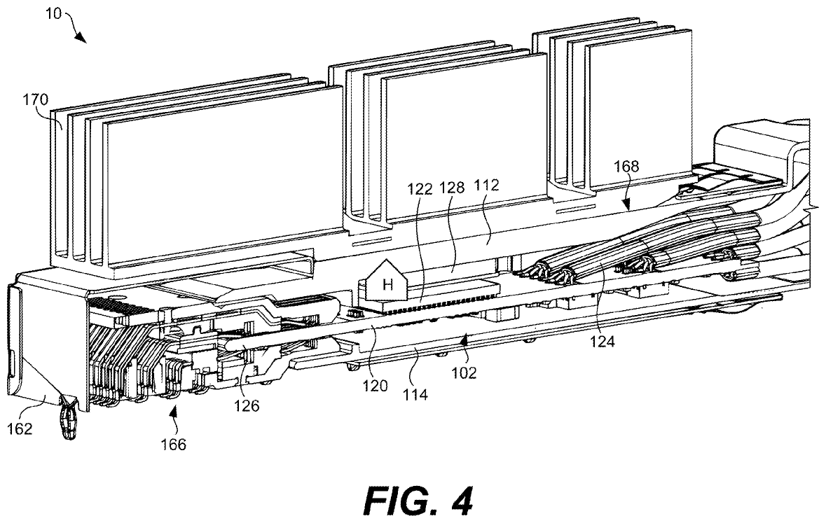

FIG. 4 illustrates the cross-sectional view of the cable assembly designated I-I in FIG. 1. As shown in FIG. 4, the module 102 includes a PCB 120. A semiconductor chip 122 is mounted over the PCB 120 and electrically coupled to metal traces on the PCB 120. A number of shielded cables, such as the shielded cable 124, have conductors that are electrically coupled and terminated to the PCB 120. The PCB 120 also includes a PCB-style tip at the end of the module 102, which is inserted into the connector 166 within the metal housing 162 in the example shown. A thermal pad 128 is positioned between the semiconductor chip 122 and the upper shell 112, and the thermal pad 128 conducts heat “H” from the semiconductor chip 122 to the upper shell 112. A bottom surface of the heat sink 170 contacts the top surface of the upper shell 112 of the module 102 over the interface 168 between them. In some cases, the thermal pad 128 can be omitted, and the top surface of the semiconductor chip 122 can directly contact the bottom inner surface the upper shell 112. Alternatively, a thermal paste can be spread between the top surface of the semiconductor chip 122 and the bottom inner surface the upper shell 112, and other arrangements are within the scope of the embodiments.

The semiconductor chip 122 consumes power and dissipates heat “H.” The heat is conducted, at least in part, through the thermal pad 128, to the upper shell 112, through the upper shell 112, and to the bottom surface of the heat sink 170. The heat sink 170 is positioned to draw and dissipate the heat “H” away from the upper shell 112 of the module 102. It can be important to extract and dissipate the heat out of and away from the module 102 for the operation of the module 102. However, many pluggable modules, such as the module 102, are not optimized for the transfer of heat to heat sinks on SFP cages. For example, although heat is transferred from the semiconductor chip 122 within the module 102, through the upper shell 112, and to the heat sink 170, the upper shell 112 is not necessarily optimized to transfer the heat. While various embodiments are described herein with respect to representative semiconductor chip 122, it is understood that the same principles may be employed with respect to other chips or processing circuitry that generate heat, as may be appreciated.

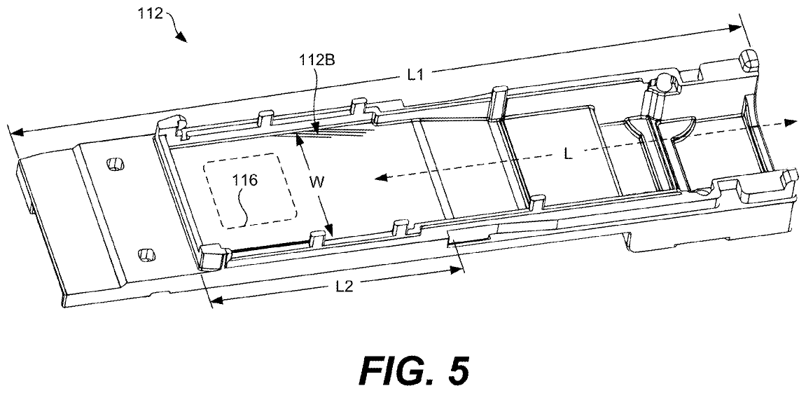

FIG. 5 illustrates a bottom view of the upper shell 112 of the module 102 shown in FIG. 3. The upper shell 112 extends a length “L1” along a longitudinal axis “L” of the upper shell 112. The upper shell 112 includes a bottom inner surface 112B, which is planar. The bottom inner surface 112B can extend in a plane parallel to a plane in which the top outer surface 112A (see FIG. 3) of the upper shell 112 extends. The inner surface 112B extends a length “L2” along the longitudinal axis “L” and a width “W,” measured perpendicular to the longitudinal axis “L.” The length “L2” of the inner surface 112B extends less than half of the full length “L1” of the upper shell 112 in the example shown. The upper shell 112 is positioned above the semiconductor chip 122 in the module 102. The region 116 of the inner surface 112B is representative of an area positioned over or above the semiconductor chip 122, when the module 102 is assembled.

According to aspects of the embodiments, shells, upper shells, or other housings of pluggable transceiver modules are improved by the inclusion of heat spreaders, such as heat pipes, vapor chambers, or other heat spreaders. The heat spreaders provide a means to more effectively transfer heat away from semiconductor chips or devices within the pluggable modules, across a larger region of the module shells or housings of the pluggable transceiver modules. In turn, the module shells conduct and transfer heat over a wider area of the outer surfaces of the shells, for improved or enhanced transfer of heat out of the modules.

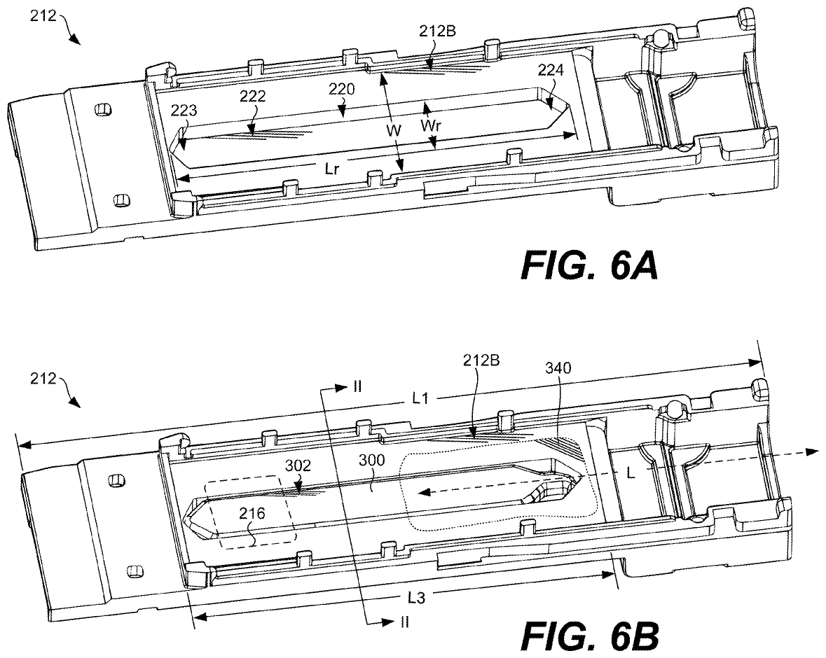

FIG. 6A illustrates a bottom view of an upper shell 212 of another cable assembly according to various embodiments of the present disclosure, and FIG. 6B illustrates the upper shell 212 shown in FIG. 6A, with a heat pipe 300. The heat pipe 300 is one example of a heat spreader that can be incorporated with an upper shell of a pluggable transceiver module according to the concepts described herein. The heat pipe 300 is representative, not drawn to scale, and can vary in shape, size, or in shape and size as compared to that shown. Additionally, the upper shell 212 is also representative, not drawn to scale, and can vary in shape, size, or in shape and size as compared to that shown. The upper shell 212 can be relied upon as part of a module shell of a pluggable transceiver module, similar to the upper shell 112 of the module 102 shown in FIG. 2 and described above.

The upper shell 212 can be embodied as or formed from a metal or metal alloy. In one example, the upper shell 212 can be embodied as a die-cast zinc, zinc alloy, or other metals or metal alloys. The upper shell 212 can be plated on exterior surfaces in some cases, such as with one or more copper, nickel, or other plating layers. The materials from which the upper shell 212 is formed is not limited, however, and the upper shell 212 can be formed from a range of materials and casting, additive, subtractive, and related manufacturing techniques.

Referring between FIGS. 6A and 6B, the upper shell 212 extends a length “L1” along a longitudinal axis “L” of the upper shell 212. The upper shell 212 includes a bottom inner surface 212B, which is planar. The bottom inner surface 212B can extend in a plane parallel to a plane in which a top outer surface of the upper shell 212 extends. The inner surface 212B extends a length “L3” along the longitudinal axis “L” and a width “W,” measured perpendicular to the longitudinal axis “L.” The length “L3” of the inner surface 212B extends more than half of the full length “L1” of the upper shell 212 in the example shown. The length “L3” of the inner surface 212B is shown as an example in FIGS. 6A and 6B, however, and the inner surface 212B can be formed to other lengths, widths, and related dimensions. In other cases, the length “L3” of the inner surface 212B can extend more than 35%, 40%, 45%, 50%, 55%, 60%, 65%, or 70% of the full length “L1” of the upper shell 212, although smaller and larger “L” dimensions can be relied upon. The length “L3” of the inner surface 212B can preferably formed to be as long as possible to accommodate a relatively large, recessed area, as described below.

The upper shell 212 includes a recessed area 220. The recessed area 220 extends in depth or height from an opening at the bottom inner surface 212B to a bottom recessed inner surface 222 of the recessed area 220. The bottom inner surface 212B of the upper shell 212 and the bottom recessed inner surface 222 of the recessed area 220 are both substantially coplanar with the top outer surface 212A of the upper shell 212 in one example. The recessed area 220 includes tapered ends 223 and 224 at opposing, distal ends of the recessed area 220. The recessed area 220 extends a length “Lr” along the longitudinal axis “L” and a width “Wr,” measured perpendicular to the longitudinal axis “L.” The “Lr,” “Wr,” and depth dimensions of the recessed area 220 can be sized to accommodate the heat pipe 300, with a minimal clearance between them, in some cases. In other cases, the upper shell 212 can interlock and mechanically interfere with one or more interlocking ledges of the heat pipe 300, as described below. The “Lr” dimension of the recessed area 220 can preferably extend over a substantial portion of the length “L3” of the inner surface 212B. As examples, “Lr” can extend over 95%, 90%, 85%, or 80% of the length “L3” of the inner surface 212B, although “Lr” can be made smaller in some cases.

As shown in FIG. 6B, the heat pipe 300 is secured within the recessed area 220. A bottom surface 302 of the heat pipe 300 is substantially coplanar with the bottom inner surface 212B of the upper shell 212, when secured within the recessed area 220. The heat pipe 300 can be secured within the recessed area 220 of the upper shell 212 in a number of different ways. For example, the heat pipe 300 can be welded or soldered within the recessed area 220 of the upper shell 212. The heat pipe 300 can also be sintered to the upper shell with a silver sinter die attach, for example, or another die attach or sintering die attach. In other cases, a thermally conductive paste can be positioned between the bottom recessed inner surface 222 of the recessed area 220 and the heat pipe 300, and the thermally conductive paste can adhere the heat pipe 300 to the inner surface 222. In still other cases, the upper shell 212 can include a die cast module shell, and the heat pipe 300 can be a die cast insert in the upper shell 212.

When assembled into a pluggable transceiver module, the upper shell 212 can be positioned above a semiconductor chip similar to the semiconductor chip 122 shown in FIG. 4. The region 216 shown in FIG. 6B is representative of an area positioned over or above the semiconductor chip, when the upper shell 212 is assembled into a pluggable transceiver module. As shown, the region 216 extends across both the bottom inner surface 212B of the upper shell 212 and the bottom surface 302 of the heat pipe 300. Thus, heat can be transferred from the semiconductor chip to the heat pipe 300.

An insulating sheet 340 can also be placed across and over at least a portion of the bottom inner surface 212B of the upper shell 212 and the bottom surface 302 of the heat pipe 300 in some cases. The insulating sheet 340 can help to electrically and thermally isolate components within the module from heat spread by the heat pipe 300, among other benefits. The shape and size of the insulating sheet 340 can vary, although the insulating sheet 340 would not extend over the region 216.

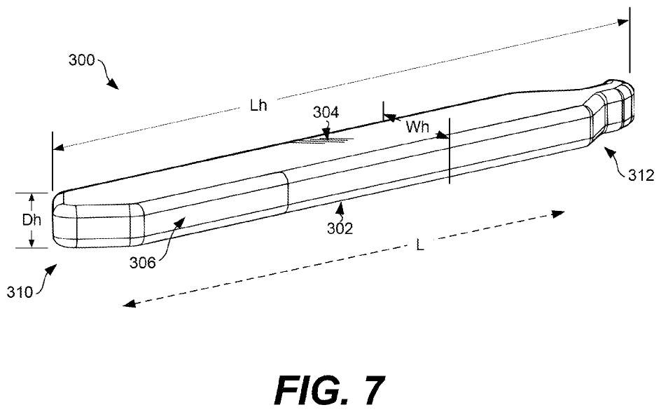

FIG. 7 illustrates the heat pipe 300 shown in FIG. 6B according to various embodiments of the present disclosure. The heat pipe 300 includes a bottom surface 302, a top surface 304, a side surface 306, and tapered ends 310 and 312. The heat pipe 300 is a type of flattened pipe or tube, in the example shown. The heat pipe 300 extends a length “Lh” along the longitudinal axis “L” and a width “Wh,” measured perpendicular to the longitudinal axis “L.” The heat pipe 300 also has a depth “Dh.” Example dimensions of the heat pipe 300 can range from between 40-100 mm in length, from between 4-10 mm in width, and from between 1.5-5 mm in depth. In one particular example, the heat pipe 300 can be about 70 mm in length, about 5.4 mm in width, and about 2 mm in depth, although the heat pipe 300 can be formed to other dimensions.

The heat pipe 300 can be embodied as a sealed pipe or tube made of a metal compatible with a working fluid that is enclosed within the heat pipe 300. As examples, the sealed pipe of the heat pipe 300 can be formed from copper or aluminum, although other metals or metal alloys can be used. The working fluid within the heat pipe 300 can be water, ammonia, or another working fluid, in a vacuum within the heat pipe 300. The working fluid, which contacts the inner surfaces of the sealed pipe, can transition into a vapor by absorbing heat from hotter inner surfaces within the sealed pipe. The vapor can then travel within the heat pipe 300 to a colder internal interface or surface region and condense back into a liquid, facilitating the transfer of heat. The working liquid can then return to the hot interface through capillary action, for example. Due to the relatively high heat transfer coefficients for boiling and condensation, the heat pipe 300 is an effective thermal conductor. Overall, the heat pipe 300 is more effective and efficient in the transfer of heat than the upper shell 212 alone.

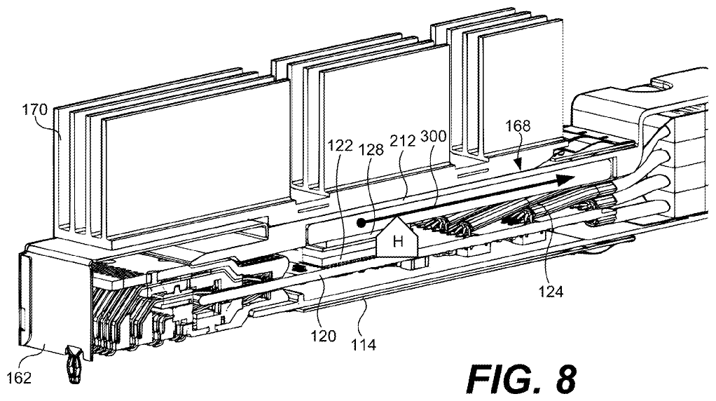

FIG. 8 illustrates a cross-sectional view of a cable assembly including the upper shell 212 and heat pipe 300 shown in FIG. 6B. A thermal pad 128 is positioned between the semiconductor chip 122 and the heat pipe 300, which is recessed into the upper shell 212. The thermal pad 128 conducts heat “H” from the semiconductor chip 122 to the heat pipe 300. In some cases, the thermal pad 128 can be omitted, and the top surface of the semiconductor chip 122 can directly contact the bottom surface the heat pipe 300. Alternatively, a thermal paste can be spread between the top surface of the semiconductor chip 122 and the heat pipe 300, and other arrangements are within the scope of the embodiments.

The semiconductor chip 122 consumes power and dissipates heat “H.” The heat is conducted through the thermal pad 128, to the heat pipe 300 and the upper shell 212, through the heat pipe 300 and the upper shell 212, and to the bottom surface of the heat sink 170. The heat sink 170 is positioned to draw and dissipate the heat “H” away from the upper shell 212, along the interface 168 between them. However, as compared to the example shown in FIG. 4, the upper shell 212 more effectively transfers heat from the semiconductor chip 122 than the upper shell 112, due to the heat pipe 300. The thermal conductivity of the heat pipe 300 is significantly larger than the upper shell 212 (and the upper shell 112), and the overall heat transfer coefficient of the upper shell 212 is significantly larger than that of the upper shell 112. Additionally, the heat pipe 300 extends along a large portion of the length of the interface 168, helping to move heat more quickly and effectively to the heat sink 170.

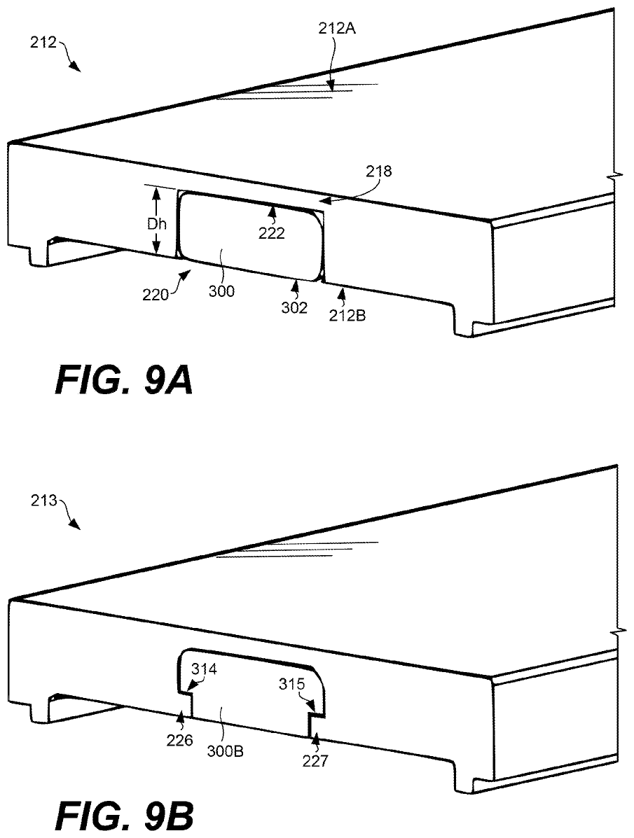

FIG. 9A illustrates the cross-sectional view of the upper shell 212 and heat pipe 300 designated II-II in FIG. 6B according to aspects of the present disclosure. As shown, the bottom surface 302 of the heat pipe 300 is substantially coplanar with the bottom inner surface 212B of the upper shell 212. Additionally, only a relatively small region 218 of the upper shell 212 remains between the bottom recessed inner surface 222 of the recessed area 220 and the top outer surface 212A of the upper shell 212. The region 218 of the upper shell 212 can be made sufficiently small to permit heat transfer from the heat pipe 300 to the heat sink 170. The region 218 should preferably be large enough, however, to maintain the structural integrity of the upper shell 212, while also maintaining the dimensional specifications of the module housing. The depth “Dh” of the heat pipe 300 (see also FIG. 7) may be thus limited or determined, in part, based on a minimal thickness of the region 218.

FIG. 9B illustrates a cross-sectional view of another upper shell 213 and heat pipe 300B according to aspects of the present disclosure. In the example shown, the upper shell 213 includes interlocking ridges 226 and 227, and the heat pipe 300B includes interlocking ledges 314 and 315. The interlocking ridges 226 and 227 of the upper shell 213 interlock and mechanically interfere with the interlocking ledges 314 and 315 of the heat pipe 300, respectively. The assembly technique shown in FIG. 9B can be achieved by forming the upper shell 213 as a die cast module shell. The heat pipe 300B can be inserted into a mold used to form the upper shell 213, before the metal alloy used to form the upper shell 213 is flowed into the mold. In the example shown, the heat pipe 300B is a type of die cast insert in the upper shell 213. This insert casting technique can minimize any free space between the heat pipe 300B and the upper shell 213 and also secure the heat pipe 300B.

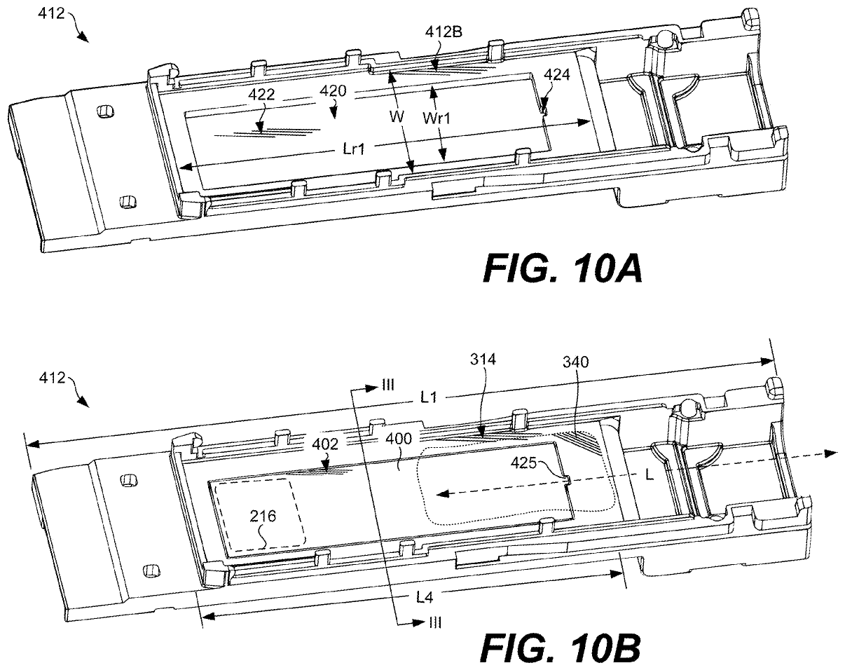

FIG. 10A illustrates a bottom view of an upper shell 412 of another cable assembly according to various embodiments of the present disclosure, and FIG. 10B illustrates the upper shell 412 shown in FIG. 10A, with a vapor chamber 400. The vapor chamber 400 is one example of a heat spreader that can be incorporated with an upper shell of a pluggable transceiver module according to the concepts described herein. The vapor chamber 400 is representative, not drawn to scale, and can vary in shape, size, or in shape and size as compared to that shown. Additionally, the upper shell 412 is also representative, not drawn to scale, and can vary in shape, size, or in shape and size as compared to that shown. The upper shell 412 can be relied upon as part of a module shell of a pluggable transceiver module, similar to the upper shell 112 of the module 102 shown in FIG. 2 and described above.

The upper shell 412 can be embodied as or formed from a metal or metal alloy. In one example, the upper shell 412 can be embodied as a die-cast zinc, zinc alloy, or other metals or metal alloys. The upper shell 412 can be plated on exterior surfaces in some cases, such as with one or more copper, nickel, or other plating layers. The materials from which the upper shell 412 is formed is not limited, however, and the upper shell 412 can be formed from a range of materials and casting, additive, subtractive, and related manufacturing techniques.

Referring between FIGS. 10A and 10B, the upper shell 412 extends a length “L1” along a longitudinal axis “L” of the upper shell 412. The upper shell 412 includes a bottom inner surface 412B, which is planar. The bottom inner surface 412B can extend in a plane parallel to a plane in which a top outer surface of the upper shell 412 extends. The inner surface 412B extends a length “L4” along the longitudinal axis “L” and a width “W,” measured perpendicular to the longitudinal axis “L.” The length “L4” of the inner surface 412B extends more than half of the full length “L1” of the upper shell 412 in the example shown. The length “L4” of the inner surface 412B is shown as an example in FIGS. 10A and 10B, however, and the inner surface 412B can be formed to other lengths, widths, and related dimensions. In other cases, the length “L4” of the inner surface 412B can extend more than 35%, 40%, 45%, 50%, 55%, 60%, 65%, or 70% of the full length “L1” of the upper shell 412, although smaller and larger “L” dimensions can be relied upon. The length “L4” of the inner surface 412B can preferably formed to be as long as possible, to accommodate a relatively large, recessed area, as described below.

The upper shell 412 includes a recessed area 420. The recessed area 420 extends in depth or height from an opening at the bottom inner surface 412B to a bottom recessed inner surface 422 of the recessed area 420. The recessed area 420 includes a recess notch 424, that can be used to help position and secure the vapor chamber 400, as described below. The recessed area 420 extends a length “Lr1” along the longitudinal axis “L” and a width “Wr1,” measured perpendicular to the longitudinal axis “L.” The “Lr1,” “Wr1.” and depth dimensions of the recessed area 420 can be sized to accommodate the vapor chamber 400, with a minimal clearance between them, in some cases. In other cases, the upper shell 412 can interlock and mechanically interfere with one or more interlocking ledges of the vapor chamber 400, as described below. The “Lr1” dimension of the recessed area 420 can preferably extend over a substantial portion of the length “L4” of the inner surface 412B. As examples, “Lr1” can extend over 95%, 90%, 85%, or 80% of the length “L4” of the inner surface 412B, although “Lr1” can be made smaller in some cases.

As shown in FIG. 10B, the vapor chamber 400 is secured within the recessed area 420. A bottom surface 402 of the vapor chamber 400 is substantially coplanar with the bottom inner surface 412B of the upper shell 412, when secured within the recessed area 420. The vapor chamber 400 can be secured within the recessed area 420 of the upper shell 412 in a number of different ways. For example, the vapor chamber 400 can be welded or soldered within the recessed area 420 of the upper shell 412. The vapor chamber 400 can also be sintered to the upper shell with a silver sinter die attach, for example, or another die attach or sintering die attach. In other cases, a thermally conductive paste can be positioned between the bottom recessed inner surface 422 of the recessed area 420 and the vapor chamber 400, and the thermally conductive paste can adhere the vapor chamber 400 to the inner surface 422. In still other cases, the upper shell 412 can include a die cast module shell, and the vapor chamber 400 can be a die cast insert in the upper shell 412.

When assembled into a pluggable transceiver module, the upper shell 412 can be positioned above a semiconductor chip similar to the semiconductor chip 122 shown in FIG. 4. The region 216 shown in FIG. 10B is representative of an area positioned over or above the semiconductor chip, when the upper shell 412 is assembled into a pluggable transceiver module. As shown, the region 216 extends over the bottom surface 402 of the vapor chamber 400. Thus, heat can be transferred from the semiconductor chip to the vapor chamber 400.

An insulating sheet 340 can also be placed across and over at least a portion of the bottom inner surface 412B of the upper shell 412 and the bottom surface 402 of the vapor chamber 400 in some cases. The insulating sheet 340 can help to electrically and thermally isolate components within the module from heat spread by the vapor chamber 400, among other benefits. The shape and size of the insulating sheet 340 can vary, although the insulating sheet 340 would not extend over the region 216.

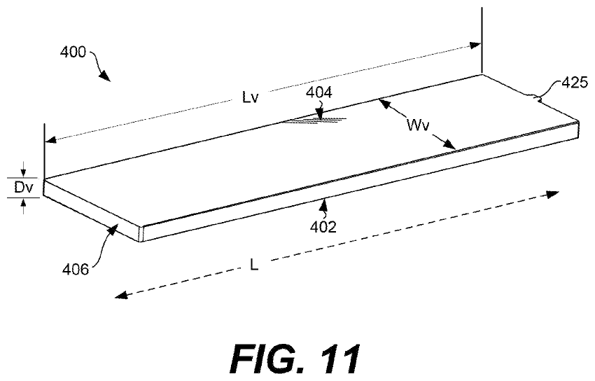

FIG. 11 illustrates the vapor chamber 400 shown in FIG. 10B according to various embodiments of the present disclosure. The vapor chamber 400 includes a bottom surface 402, a top surface 404, and a side surface 406. The vapor chamber 400 also includes a positioning detent 425. The positioning detent 425 can fit into the recess notch 424 of the recessed area 420, to help position and secure the vapor chamber 400 within the recessed area 420 of the upper shell 412, as shown in FIG. 10B.

The vapor chamber 400 extends a length “Lv” along the longitudinal axis “L” and a width “Wv,” measured perpendicular to the longitudinal axis “L.” The vapor chamber 400 also has a depth “Dv.” Example dimensions of the vapor chamber 400 can range from between 30-100 mm in length, from between 8-12 mm in width, and from between 1-3 mm in depth. In one particular example, the vapor chamber 400 can be about 35 mm in length, about 10 mm in width, and about 1 mm in depth, although the vapor chamber 400 can be formed to other dimensions.

The vapor chamber 400 can be embodied as a planar chamber of metal compatible with a working fluid that is enclosed within the vapor chamber 400. As examples, the sealed chamber of the vapor chamber 400 can be formed from copper or aluminum, although other metals or metal alloys can be used. The working fluid within the vapor chamber 400 can be water, ammonia, or another working fluid, in a vacuum within the vapor chamber 400. The working fluid, which contacts the inner surfaces of the sealed chamber, can transition into a vapor by absorbing heat from hotter inner surfaces within the sealed chamber. The vapor can then travel within the vapor chamber 400 to a colder internal interface or surface region and condense back into a liquid, facilitating the transfer of heat. The working liquid can then return to the hot interface through capillary action, for example. Due to the relatively high heat transfer coefficients for boiling and condensation, the vapor chamber 400 is an effective thermal conductor. Overall, vapor chamber 400 is more effective and efficient in the transfer of heat than the upper shell 412 alone.

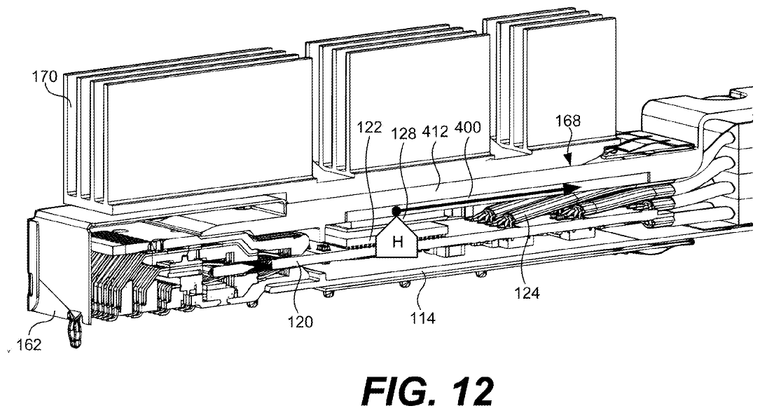

FIG. 12 illustrates a cross-sectional view of a cable assembly including the upper shell 412 and vapor chamber 400 shown in FIG. 10B. A thermal pad 128 is positioned between the semiconductor chip 122 and the vapor chamber 400, which is recessed into the upper shell 412. The thermal pad 128 conducts heat “H” from the semiconductor chip 122 to the vapor chamber 400. In some cases, the thermal pad 128 can be omitted, and the top surface of the semiconductor chip 122 can directly contact the bottom surface the vapor chamber 400. Alternatively, a thermal paste can be spread between the top surface of the semiconductor chip 122 and the vapor chamber 400, and other arrangements are within the scope of the embodiments.

The semiconductor chip 122 consumes power and dissipates heat “H.” The heat is conducted through the thermal pad 128, to the vapor chamber 400, through the vapor chamber 400 and the upper shell 412, and to the bottom surface of the heat sink 170. The heat sink 170 is positioned to draw and dissipate the heat “H” away from the upper shell 412, along the interface 168 between them. However, as compared to the example shown in FIG. 4, the upper shell 412 more effectively transfers heat from the semiconductor chip 122 than the upper shell 112, due to the vapor chamber 400. The thermal conductivity of the vapor chamber 400 is significantly larger than the upper shell 412 (and the upper shell 112), and the overall heat transfer coefficient of the upper shell 412 is significantly larger than that of the upper shell 112. Additionally, the vapor chamber 400 extends along a large portion of the length of the interface 168, helping to move heat more quickly and effectively to the heat sink 170.

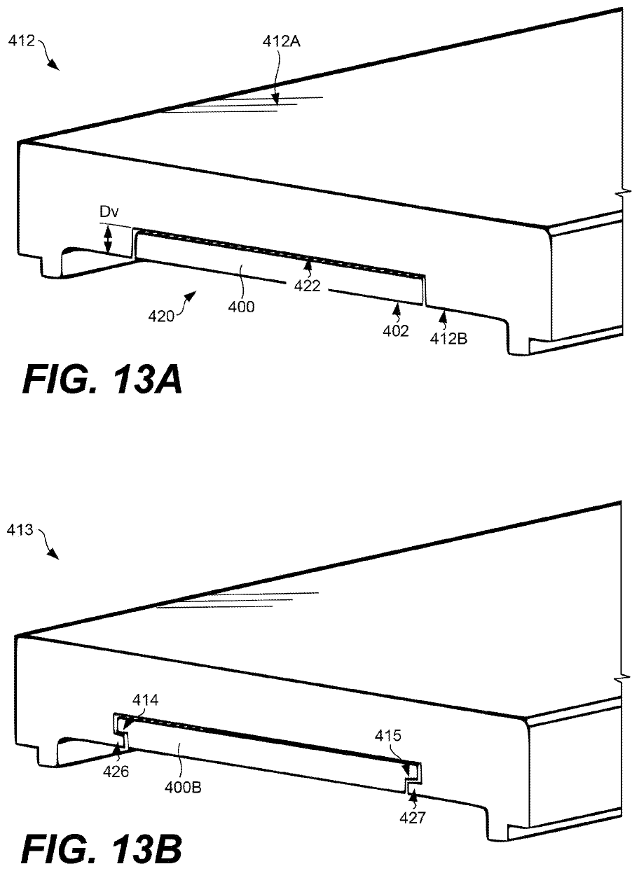

FIG. 13A illustrates the cross-sectional view of the upper shell 412 and vapor chamber 400 designated III-III in FIG. 10B according to aspects of the present disclosure. As shown, the bottom surface 402 of the vapor chamber 400 is substantially coplanar with the bottom inner surface 412B of the upper shell 412. FIG. 13B illustrates a cross-sectional view of another upper shell 413 and vapor chamber 400B according to other aspects of the present disclosure. In the example shown, the upper shell 413 includes interlocking ridges 426 and 427, and the vapor chamber 400B includes interlocking ledges 414 and 415. The interlocking ridges 426 and 427 of the upper shell 413 interlock and mechanically interfere with the interlocking ledges 414 and 415 of the vapor chamber 400B, respectively. The assembly technique shown in FIG. 13B can be achieved by forming the upper shell 413 as a die cast module shell. The vapor chamber 400B can be inserted into a mold used to form the upper shell 413, before the metal alloy used to form the upper shell 413 is flowed into the mold. In the example shown, the vapor chamber 400B is a type of die cast insert in the upper shell 413. This insert casting technique can minimize free space between the vapor chamber 400B and the upper shell 413 and also secure the vapor chamber 400B.

Terms such as “top,” “bottom,” “side.” “front,” “back,” “right,” and “left” are not intended to provide an absolute frame of reference. Rather, the terms are relative and are intended to identify certain features in relation to each other, as the orientation of structures described herein can vary. The terms “comprising.” “including.” “having,” and the like are synonymous, are used in an open-ended fashion, and do not exclude additional elements, features, acts, operations, and so forth. Also, the term “or” is used in its inclusive sense, and not in its exclusive sense, so that when used, for example, to connect a list of elements, the term “or” means one, some, or all of the elements in the list.

Combinatorial language, such as “at least one of X. Y, and Z” or “at least one of X, Y, or Z,” unless indicated otherwise, is used in general to identify one, a combination of any two, or all three (or more if a larger group is identified) thereof, such as X and only X, Y and only Y, and Z and only Z, the combinations of X and Y, X and Z, and Y and Z, and all of X, Y, and Z. Such combinatorial language is not generally intended to, and unless specified does not, identify or require at least one of X, at least one of Y, and at least one of Z to be included.

The terms “about” and “substantially,” unless otherwise defined herein to be associated with a particular range, percentage, or related metric of deviation, account for at least some manufacturing tolerances between a theoretical design and manufactured product or assembly, such as the geometric dimensioning and tolerancing criteria described in the American Society of Mechanical Engineers (ASME®) Y14.5 and the related International Organization for Standardization (ISO®) standards. Such manufacturing tolerances are still contemplated, as one of ordinary skill in the art would appreciate, although “about,” “substantially,” or related terms are not expressly referenced, even in connection with the use of theoretical terms, such as the geometric “perpendicular,” “orthogonal,” “vertex,” “collinear,” “coplanar,” and other terms.

The above-described embodiments of the present disclosure are merely examples of implementations to provide a clear understanding of the principles of the present disclosure. Many variations and modifications can be made to the above-described embodiments without departing substantially from the spirit and principles of the disclosure. In addition, components and features described with respect to one embodiment can be included in another embodiment. All such modifications and variations are intended to be included herein within the scope of this disclosure.

At least the following is claimed:

1. A pluggable transceiver module, comprising:
a module shell, the module shell comprising an upper shell and a lower shell, the upper shell comprising a planar inner surface and a recessed area formed into the planar inner surface;
a printed circuit board;
a chip mounted on the printed circuit board; and
a heat spreader secured within the recessed area, between the upper shell and the chip.

2. The module according to claim 1, further comprising a thermal pad positioned between the chip and the heat spreader.

3. The module according to claim 1, wherein the heat spreader is secured within the recessed area with a surface of the heat spreader being substantially coplanar with the planar inner surface of the upper shell.

4. The module according to claim 1, wherein the heat spreader is welded to the upper shell.

5. The module according to claim 1, wherein the heat spreader is sintered to the upper shell with silver sinter die attach.

6. The module according to claim 1, wherein:
the upper shell comprises a die cast upper shell; and
the heat spreader is a die cast insert in the die cast upper shell.

7. The module according to claim 1, wherein:
the heat spreader comprises an interlocking ledge; and
the upper shell secures the heat spreader within the recessed area by mechanical interference with the interlocking ledge.

8. The module according to claim 1, wherein:
the heat spreader comprises a positioning detent;
the upper shell comprises a recess notch; and
the heat spreader is secured within the recessed area with the positioning detent extending into the recess notch.

9. The module according to claim 1, further comprising an insulating sheet extending over at least a portion of the heat spreader.

10. The module according to claim 1, wherein the heat spreader extends in length over at least half of a length of the upper shell, along a longitudinal axis of the upper shell.

11. The module according to claim 1, wherein the heat spreader comprises a heat pipe.

12. The module according to claim 1, wherein the heat spreader comprises a vapor chamber.

13. The module according to claim 1, wherein:
the recessed area comprises a recessed inner surface; and
the recessed inner surface is substantially coplanar with a planar outer surface of the upper shell.

14. A transceiver module, comprising:
a module shell comprising a planar inner surface and a recessed area formed into the planar inner surface;
a chip mounted on a printed circuit board; and
a heat spreader secured within the recessed area, between the module shell and the chip.

15. The module according to claim 14, wherein the heat spreader is secured within the recessed area with a surface of the heat spreader being substantially coplanar with the planar inner surface of the module shell.

16. The module according to claim 14, wherein the heat spreader is welded within the recessed area of the module shell.

17. The module according to claim 14, wherein the heat spreader is sintered within the recessed area of the module shell with silver sinter die attach.

18. The module according to claim 14, wherein:
the module shell comprises a die cast module shell; and
the heat spreader is a die cast insert in the die cast module shell.

19. The module according to claim 14, wherein:
the heat spreader comprises an interlocking ledge; and
the module shell secures the heat spreader within the recessed area by mechanical interference with the interlocking ledge.

20. The module according to claim 14, wherein:
the heat spreader comprises a positioning detent;
the module shell comprises a recess notch; and
the heat spreader is secured within the recessed area with the positioning detent extending into the recess notch.
